(19) United States
(12) Patent Application Publication
(10) Pub. No.: US 2009/0239362 A1
(43) Pub. Date: Sep. 24, 2009

(54) APPARATUS FOR MANUFACTURING SEMICONDUCTOR DEVICE AND METHOD FOR MANUFACTURING SEMICONDUCTOR DEVICE

(76) Inventors: Hironobu Hirata, Mishima-shi (JP); Shinichi Mitani, Numazu-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/406,796

(22) Filed: Mar. 18, 2009

(30) Foreign Application Priority Data
Mar. 24, 2008 (JP) 2008-075956

(51) Int. Cl. H01L 21/20; B05C 11/00; B05C 1/00

(52) U.S. Cl. 438/509; 118/728; 118/708; 118/724; 257/E21.106

(57) ABSTRACT

An apparatus for manufacturing a semiconductor device, including in a reaction chamber: a rotor provided with a holding member holding a wafer thereon and a heater heating the wafer therein; a rotation drive mechanism; a gas supply mechanism; a gas exhaust mechanism; and a rectifying plate for rectifying the supplied process gas to supply the rectified gas, and including: an annular rectifying fin mounted on a lower portion of the plate, having a larger lower end inside diameter than an upper end inside diameter thereof and downward rectifying gas exhausted in an outer circumferential direction from above the wafer; and a distance control mechanism controlling a vertical distance between the plate and the wafer and a vertical distance between the fin and the rotor top face to be predetermined distances, respectively, thereby providing higher film formation efficiency.

### CROSS-REFERENCE TO RELATED APPLICATION

This application is based upon and claims the benefit of priority from the prior Japanese Patent Application No. 2008-075956 filed on Mar. 24, 2008, the entire contents of which are incorporated herein by reference.

### BACKGROUND OF THE INVENTION

1. Field of the Invention

The present invention relates to an apparatus for manufacturing a semiconductor device and a method for manufacturing a semiconductor device, which, for example, supplies process gas onto a semiconductor wafer while heating the wafer and forms a film on the wafer while performing high-speed rotation.

2. Description of the Related Art

In recent years, with requirements for further price reduction and higher performance of semiconductor devices, there have been requested higher productivity in a film formation process as well as improvement in uniformity of film thickness and dust reduction.

As a method used to satisfy such requests, Japanese Patent Application Laid-Open No. 11-67675 discloses a method for film formation by heating while performing high-speed rotation, using a single-wafer type epitaxial film formation apparatus. In addition, there has been an expectation for higher productivity by use of a large-diameter wafer of, for example, φ300 mm and highly efficient use of inexpensive Cl source gas such as trichlorosilane (hereinafter referred to as “TCS”) and dichlorosilane.

However, in forming a thick epitaxial film having a film thickness in excess of 150 μm to be used for, for example, an IGBT (insulated gate bipolar transistor), there is a problem that high productivity is difficult to ensure.

### SUMMARY OF THE INVENTION

It is an object of the present invention to provide an apparatus for manufacturing a semiconductor device and a method for manufacturing a semiconductor device, with higher film formation speed and utilization efficiency of source gas and thus capable of attaining high productivity.

According to an aspect of the present invention, there is provided an apparatus for manufacturing a semiconductor device including: a reaction chamber in which a wafer is introduced and is subjected to film formation; a rotor provided with a holding member holding the introduced wafer at an upper portion thereof and a heater heating the wafer therein; a rotation drive mechanism connected with the rotor and rotating the wafer; a gas supply mechanism supplying a predetermined flow rate of process gas to the reaction chamber; a gas exhaust mechanism exhausting gas from the reaction chamber and controlling the pressure in the reaction chamber to be a predetermined pressure; and a rectifying plate rectifying the process gas and supplying the gas onto the wafer hold on the holding member. The apparatus further includes: an annular rectifying fin mounted on a lower portion of the rectifying plate, having a larger lower end inside diameter than an upper end inside diameter thereof and downward rectifying gas exhausted in an outer circumferential direction from above the wafer; and a distance control mechanism for controlling a vertical distance between the rectifying plate and the wafer and a vertical distance between the rectifying fin and the rotor top face to be predetermined distances, respectively.

According to another aspect of the present invention, there is provided a method for manufacturing a semiconductor device, including: holding a wafer in a reaction chamber; controlling the pressure in the reaction chamber to be a predetermined pressure; rectifying process gas and supplying the process gas onto the wafer from above while heating and rotating the wafer; and discharging surplus process gas and exhaust gas above the wafer containing reaction by-product generated by the process gas in an outer circumferential direction from above the wafer by the rotation of the wafer. The method further includes: controlling at least a height of a space above the periphery of the wafer so that a backflow rate, flowing onto the wafer, of the exhaust gas discharged in the outer circumferential direction is a predetermined value; and rectifying the exhaust gas at a predetermined gradient above the periphery of the wafer and discharging the exhaust gas downward.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view of an apparatus for manufacturing a semiconductor device according to an aspect of the present invention;

FIG. 2A illustrates a conventional gas flow;

FIG. 2B is illustrates a gas flow according to an aspect of the present invention;

FIGS. 3 to 5 are sectional views of an apparatus for manufacturing a semiconductor device according to an aspect of the present invention, respectively;

FIG. 6 is a structural sectional view of a rectifying fin according to an aspect of the present invention; and

FIG. 7 is a sectional view of a super junction structure according to an aspect of the present invention.

### DETAILED DESCRIPTION OF THE EMBODIMENTS

Embodiments according to the present invention will be described with reference to the drawings.

### First Embodiment

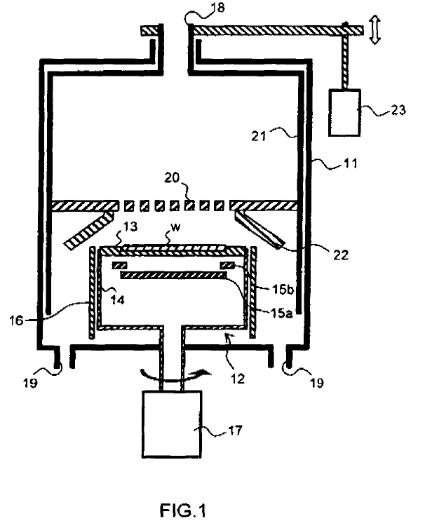

FIG. 1 is a sectional view of an apparatus for manufacturing a semiconductor device according to the present embodiment. In a reaction chamber 11 which a wafer w is loaded and subjected to film formation, a rotor 12 is installed. At the upper portion of the rotor 12, a holding member 13 for holding a loaded wafer is loaded, below which a ring 14 for supporting the holding member 13 is provided. Inside the ring 14, there are disposed an in-heater 15a and an out-heater 15b for heating a wafer w, and the like.

Around an outer periphery of the rotor 12, there is disposed a reflection board 16 for increasing thermal efficiency by reflecting radiated heat. The rotor 12 is connected to a rotation drive mechanism 17 for rotating the wafer w through an opening at a lower portion of the reaction chamber 11.

At the top of the reaction chamber 11, there is disposed a gas supply port 18 which configures a gas supply mechanism, connected with a mechanism for controlling the types of gas and the flow rate thereof (not illustrated), supplies a predetermined flow of process gas. At the bottom of the reaction chamber 11, there is disposed a gas exhaust port 19 which configures a gas supply mechanism connected with a pressure gauge (not illustrated), a pump (not illustrated) and the like, exhausts gas from the reaction chamber 11 and controls a pressure in the reaction chamber 11 to be a predetermined pressure.

Above the rotor 12, there is provided a rectifying plate 20 which rectifies supplied process gas and supplies the rectified gas onto the wafer. The rectifying plate 20 is integrated with a liner 21 covering a wall surface of the reaction chamber 11. On the underside of the rectifying plate 20, there is fixed an annular rectifying fin 22 which has a larger lower end inside diameter than an upper end inside diameter thereof, is made of, for example, quartz and downward rectifies gas exhausted in an outer circumferential direction from above the wafer w.

The liner 21 integrated with the rectifying plate 20 and the rectifying fin 22 is connected with a lifting mechanism 23 mounted outside the reaction chamber 11 and moves the liner 21 up and down to control a vertical distance between the rectifying plate 20 and the wafer w which is a height of the space above the wafer and a vertical distance between the rectifying fin 22 and a top face of the rotor 12 which is a height of the space above a periphery of the wafer to be predetermined distances, respectively.

Using such an apparatus for manufacturing a semiconductor device, for example, a Si epitaxial film is formed on a Si wafer. A wafer w of, for example, φ200 mm is introduced into the reaction chamber 11 and placed on the holding member 13. The downward movement of the liner 21 brings the rectifying plate 20 and the wafer w, and the rectifying fin 22 and the top face of the rotor 12 closer to each other by the same variation, respectively, thus the distances are controlled to be the respective predetermined distances. The in-heater 15a and the out-heater 15b control a temperature of the wafer w to be 1100° C. The rotation drive mechanism 17 rotates the wafer w, for example, at a speed of 900 rpm.

The process gas prepared to have a TCS concentration of, for example, 2.5% is introduced at, for example, 50 SLM from the gas supply port 18. The process gas is supplied onto the wafer w in a rectifyd state through the rectifying plate 20 to grow a Si epitaxial film on the wafer w.

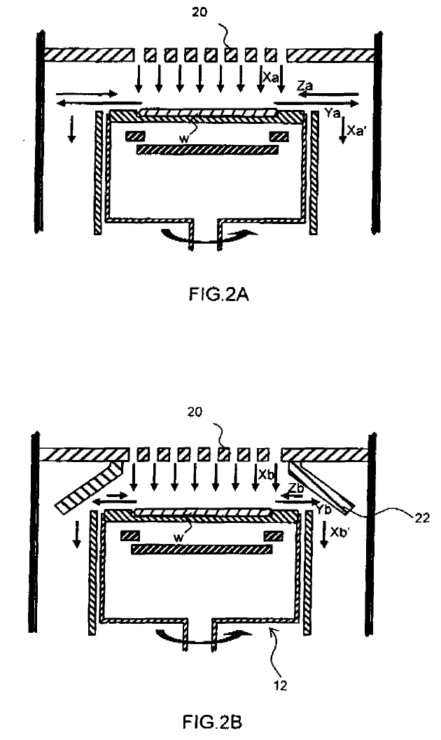

FIGS. 2A schematically illustrates a gas flow, respectively. Exhaust gas, such as surplus process gas containing TCS and dilution gas supplied onto the wafer W, and HCl which is a reaction by-product, is exhausted in the outer circumferential direction by rotation of the wafer w, as indicated by an arrow. However, at this time, a part of gas is flowed back onto the wafer w by convection or the like.

In epitaxial growth using Cl source gas, if, for example, TCS is used, the following expression (1) is obtained when TCS and H₂ are supplied:

SiHCl₃+H₂→Si+3HCl (1).

As the reaction of the above (1) proceeds to the right, a Si epitaxial film is formed, but HCl is also produced together with Si. The reaction shown by the above (1) is an equilibrium reaction formed of a plurality of reactions and therefore HCl to be exhausted flows back and, if gas is not displaced, a HCl mole ratio on the wafer w becomes higher and equilibrium shifts to the left. It is regarded that this restrains the advance of a Si generation reaction, thus lowering an epitaxial growth rate.

Hence, it is expected that control of a backflow of gas restrain the epitaxial growth rate from lowering. As illustrated in FIG. 23 by attaching the rectifying fin 22 to rectify and to exhaust the gas downward above the periphery of the wafer, the backflow of the gas can be prevented to some degree. A viscous flow is generated when a mean free path λ of molecules in the process gas inversely proportional to a pressure is sufficiently smaller than a size L of the reaction chamber 11. When the inside of the reaction furnace 11 is controlled to be above, for example, approximately 1333 Pa (10 Torr) or more, a viscous flow is generated inside the reaction furnace 11.

When the viscous flow is generated, the viscous resistance increases as a clearance relative to the holding member 13 becomes narrower due to the rectifying fin 22. An increase in the viscous resistance restrains a flow in the outer circumferential direction. Since a difference between a flow rate in the outer circumferential direction and a backflow rate is constant and almost the same as a supply rate of process gas, the backflow rate can be reduced by restraining the flow in the outer circumferential direction.

In a case where such a rectifying fin 22 is provided, the backflow rate depends upon a vertical distance between the rectifying plate 20 and the wafer w and a vertical distance between the rectifying fin 22 and the top face of the rotor 12. By reducing the vertical distance, not the horizontal distance, viscous resistance increases, and thus generation of a backflow can be restrained.

For example, reduction in the vertical distance between the rectifying plate 20 and the wafer w to approximately 40% allows the backflow rate to be reduced to approximately 40%. Reduction in the vertical distance between the rectifying fin 22 and the top face of the rotor 12 to approximately 1/14 allows the backflow rate to be restrained to ⅓ or less.

To load and place the wafer w on the holding member 13, a lower end of the rectifying fin 22 is required to be mounted above the top face of the wafer w to some degree. If the rectifying fin 22 is fixed, there is a structural limit in reducing the vertical distance. Therefore, by lowering the rectifying plate 20 and the rectifying fin 22 after the wafer w is placed on the holding member 13, the vertical distance can be reduced.

By mounting the rectifying fin 22 with a reduced vertical distance, a backflow can be restrained to approximately 40% as compared to a case where the rectifying fin 22 is not mounted, which allows an epitaxial growth rate to increase by approximately 4%.

Deposits accumulate on the rectifying fin 22 due to the process gas flow. Restraining the backflow allows dust caused by deposits generated at the rectifying fin 22 to be restrained from adhering to the wafer w. Further, restraining an influence of the backflow upon a flow of process gas onto the wafer w improves uniformity in a film thickness within a wafer surface by approximately 2%.

On the other hand, the backflow rate of gas depends upon a rotational speed and has a tendency of increasing with the rotational speed increase. This is caused by the fact that high-speed rotation generates a centrifugal force and hence a flow rate in the outer circumferential direction increases. When the rotational speed is increased by a process, the backflow rate increases, thus the film forming rate and the like fluctuate, causing the problem that a process window (margin) is difficult to ensure.

In such a case, in increasing a rotational speed with a constant gas supply volume according to process recipe, the rectifying plate 20 and the rectifying fin 22 are lowered. On the other hand, in decreasing the rotational speed, the rectifying plate 20 and the rectifying fin 22 are raised. By controlling a vertical distance according to a rotational speed in this way, a backflow rate can be kept constant and a process window can be ensured.

In the present embodiment, the reflection board 16 for increasing thermal efficiency by reflecting radiated heat is disposed around the outer periphery of the rotor 12. The backflow rate also depends upon a distance between the reflection board 16 and the rectifying fin 22. Therefore, to restrain the backflow rate, it is also effective to reduce the distance between the reflection board 16 and the rectifying fin 22. When the upper end of the reflection board 16 projects higher than the top face of the rotor 12 such as the holding member 13, convection occurs between the reflection board 16 and the top face of the rotor 12. Therefore, preferably, the upper end of the reflection board 16 is attached so as not to project higher than the top face of the rotor 12.

### Second Embodiment

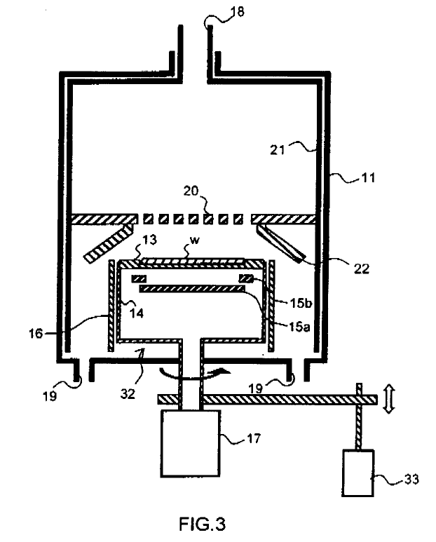

FIG. 3 illustrates a sectional view of an apparatus for manufacturing a semiconductor device according to the present embodiment. The structure of the reaction chamber 11 is almost the same as that of the first embodiment, but is different in that a lifting mechanism 33 is connected with a rotor 32, instead of a liner 21.

By using such an apparatus for manufacturing a semiconductor device, for example, a Si epitaxial film can be formed on a Si wafer in the same way as in the first embodiment and the same effects as in the first embodiment can be achieved.

Preferably, the in-heater 15a, the out-heater 15b and the like disposed in the rotor 32 are also moved up and down together with the rotor 32 in order to restrain variation in heating conditions. The reflection board 16 is also preferably moved up and down together with the rotor 32 in terms of the restraint of variation in heat reflection efficiency and of the backflow.

### Third Embodiment

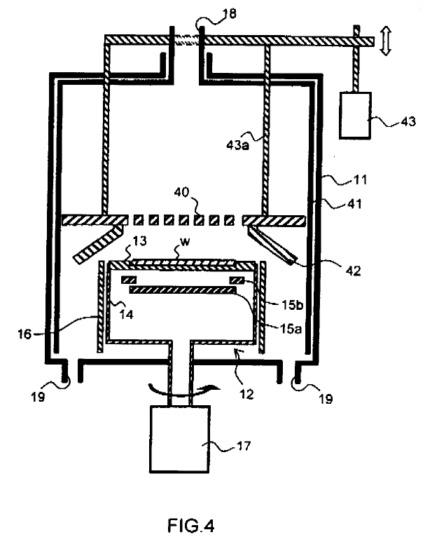

FIG. 4 illustrates a sectional view of an apparatus for manufacturing a semiconductor device according to the present embodiment. The structure of the reaction chamber 11 is almost the same as that of the first embodiment, but is different in that a lifting mechanism 43 is not connected with a liner 41 but is separated from the liner 41 and connected with a rectifying plate 40 integrated with a rectifying fin 42. The lifting mechanism 43 is connected with the rectifying plate 40 through a plurality of (e.g. three) shafts 43a connected via bellows piping or the like and is structured to move up and down.

By using such an apparatus for manufacturing a semiconductor device, for example, a Si epitaxial film can be formed on a Si wafer in the same way as in the first embodiment and the same effects as in the first embodiment can be achieved.

### Fourth Embodiment

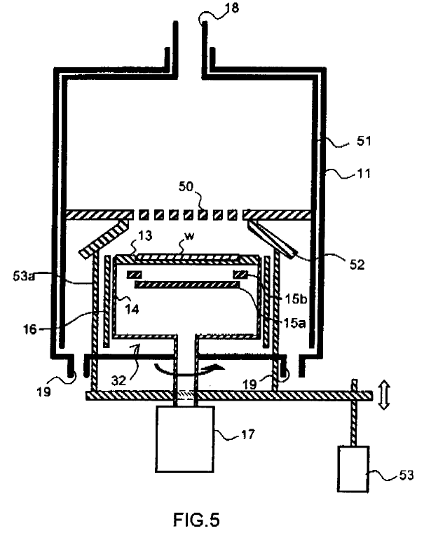

FIG. 5 illustrates a sectional view of an apparatus for manufacturing a semiconductor device according to the present embodiment. The structure of the reaction chamber 11 is almost the same as that of the first embodiment, but is different in that a lifting mechanism 53 is not connected with a liner 51 but is connected with a rectifying fin 52 separated from a rectifying plate 50. Therefore, the rectifying plate 50 cannot be moved up and down, but a distance between the rectifying fin 52 and a top face of the rotor 12, which most contributes to restraint of a backflow rate, can be controlled, thus achieving advantageous effects with a simple structure. The lifting mechanism 53 is connected with the rectifying plate 50 through a plurality of (e.g. three) shafts 53a connected via bellows piping or the like and is structured to move up and down.

By using such an apparatus for manufacturing a semiconductor device, for example, a Si epitaxial film can be formed on a Si wafer in the same way as in the first embodiment and the same effects as in the first embodiment can be achieved.

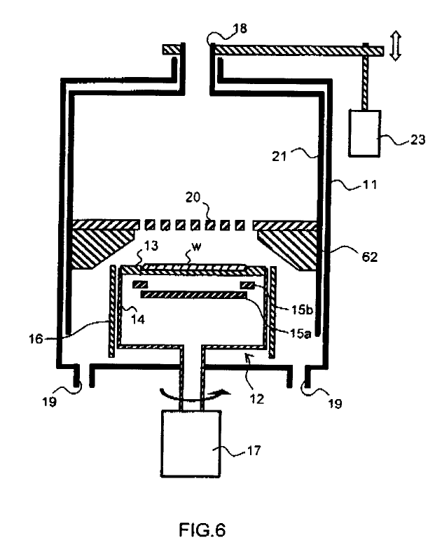

In these embodiments, the rectifying fin is of an annular body having an approximately rectangular cross section, but a gap between the fin and the liner may be filled, as illustrated in FIG. 6. Further, the rectifying fin may have a bulk shape integrated with a filler. In the case of a structure without a liner, a gap between the fin and the reaction chamber is filled. By applying a filler having high thermal conductivity in this way, the rectifying fin is cooled down, for example, to approximately 600° C., thus making it difficult to form deposits on a surface of the rectifying fin.

In addition, by using SiC or a material having carbon covered with SiC for the rectifying fin, the rectifying fin can be provided with a function as a reflection plate for reflecting heat radiation from a heater, thus increasing heating efficiency by the heater. Further, by induction heating thereof, the rectifying fin can be provided with a function as a heater, thus effectively restraining heat radiation of a wafer peripheral edge.

According to the embodiments described above, film formation rate and utilization efficiency of source gas are increased and hence a film such as an epitaxial film can be formed on a semiconductor wafer w with high productivity. In addition, higher yield of semiconductor devices formed through an element formation process and an element separation process and stability of element characteristics as well as higher wafer yield can be achieved.

In particular, excellent element characteristics can be obtained by application of the embodiments to an epitaxial formation process for a power semiconductor device such as a power MOSFET and an IGBT, which requires film thickness growth of 100 μm or more in a n-type base region, p-type base region, an insulation separation region or the like.

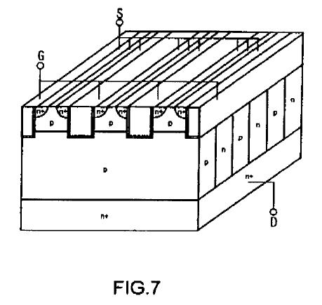

Further, in these power semiconductor devices, the embodiments can be favorably used, particularly, in forming a super junction structure as illustrated in FIG. 7. In forming such a super junction structure, after a p-type epitaxial film is formed, a fine groove is formed using a photolithography method and an n-type epitaxial film is formed in the groove. Since an epitaxial film can be smoothly formed in an ideal rectifying state even in the fine groove by restraining the backflow, an excellent super junction structure can be formed.

While the epitaxial film is formed on an Si substrate in this embodiment, it can be applied to forming of a polysilicon layer and it can be applied also to other compound semiconductors, for example, a GaAs layer, a GaAlAs layer, and an InGaAs layer. It can also be applied to forming of a SiO₂ film and a Si₃N; film, and in the case of SiO₂ film, monosilane (SiH₄) and gases of N₂, O₂, and Ar are fed, and in the case of Si₃N₄ film, monosilane (SiH₄) and gases of NH₃, N₂, O₂, and Ar are fed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An apparatus for manufacturing a semiconductor device, comprising:
a reaction chamber for loading a wafer subjected to film formation;
a rotor provided with a holding member for holding the wafer loaded at an upper portion of the rotor and the rotor with a heater heating the wafer inside the rotor;
a rotation drive mechanism connected with the rotor and the rotation drive mechanism for rotating the wafer;
a gas supply mechanism for supplying a predetermined flow rate of process gas to the reaction chamber;
a gas exhaust mechanism for exhausting gas from the reaction chamber to control the pressure in the reaction chamber to be a predetermined pressure;
a rectifying plate rectifying the process gas supplied and the plate supplying the process gas onto the wafer hold on the holding member;
an annular rectifying fin mounted on a lower portion of the rectifying plate, the fin having a larger lower end inside diameter than an upper end inside diameter of the fin and the fin rectifying downward gas exhausted in an outer circumferential direction from above the wafer; and
a distance control mechanism for controlling a vertical distance between the rectifying plate and the wafer and a vertical distance between the rectifying fin and the rotor top face to be predetermined distances, respectively.

2. The apparatus according to claim 1, wherein the distance control mechanism moves the rectifying fin or the rotor up and down.

3. The apparatus according to claim 1, wherein the distance control mechanism is controlled based on a rotational speed by the rotation drive mechanism.

4. The apparatus according to claim 1, wherein the rectifying fin is connected with the rectifying plate.

5. The apparatus according to claim 2, wherein the distance control mechanism moves the rectifying plate up and down.

6. The apparatus according to claim 1, further comprising a liner provided in the vicinity of a wall surface of the reaction chamber.

7. The apparatus according to claim 6, wherein the rectifying fin is integrated with the liner.

8. The apparatus according to claim 7, wherein the distance control mechanism moves the liner up and down.

9. The apparatus according to claim 7, wherein a gap between the rectifying fin and the liner is filled.

10. The apparatus according to claim 1, wherein the rectifying fin has a conductive material and is connected with a voltage application mechanism to be induction-heated.

11. The apparatus according to claim 1, wherein a material having SiC or carbon covered with SiC is used for the rectifying fin.

12. The apparatus according to claim 1, wherein the rectifying fin is a reflection board for reflecting heat radiated from a heater.

13. The apparatus according to claim 1, further comprising a reflection board around an outer periphery of the rotor.

14. A method for manufacturing a semiconductor device, comprising:
holding a wafer in a reaction chamber;
controlling the pressure in the reaction chamber to be a predetermined pressure;
supplying the process gas rectified onto the wafer from above with heating and rotating the wafer;
discharging surplus process gas and exhaust gas above the wafer containing reaction by-product generated by the process gas in an outer circumferential direction from above the wafer by the rotation of the wafer;
controlling at least a height of a space above the periphery of the wafer so that a backflow rate, flowing onto the wafer, of the exhaust gas discharged in the outer circumferential direction is a predetermined value; and
rectifying the exhaust gas at a predetermined gradient above the periphery of the wafer and discharging the exhaust gas downward.

15. The method according to claim 14, wherein the height of a space above the wafer is controlled by the same variation as the height of the space above the periphery of the wafer.

16. The method according to claim 14, wherein only the height of the space above the periphery of the wafer is controlled.

17. The method according to claim 14, wherein the heights of the spaces formed above the wafer and above the periphery of the wafer are controlled based on a rotational speed of the wafer.

18. The method according to claim 14, wherein cooling is performed from above the periphery of the wafer.

19. The method according to claim 14, wherein heating is performed from above the periphery of the wafer.

20. The method according to claim 14, wherein heat radiation is reflected from above the periphery of the wafer.
